(19) United States
(12) Patent Application Publication
(10) Pub. No.: US 2026/0312567 A1
(43) Pub. Date: Oct. 8, 2026

(54) PASSIVE SWITCHED-CAPACITOR FILTER WITH TUNABLE COMPLEX POLES

(71) Applicant: Apple Inc., Cupertino, CA (US)

(72) Inventors: Mohammad Reza NABAVI, Munich (DE); Corentin POCHET, Munich (DE); Sourja RAY, Cupertino, CA (US); Vahid Majidzadeh BAFAR, Los Altos, CA (US)

(21) Appl. No.: 19/098,838

(22) Filed: Apr. 2, 2025

(51) Int. Cl. H03H 11/12

(52) U.S. Cl. CPC H03H 11/12

(57) ABSTRACT

A filter circuit that employs both an active filter circuit and a switched-capacitor filter circuit is disclosed. The active filter circuit may suppress high-frequency blocker signals near a sampling frequency of the switched-capacitor filter circuit to generate a pre-filtered signal. The switched-capacitor filter circuit may employ feedback to introduce a complex pole into the transfer circuit of the filter circuit. A load-driver circuit may be used to buffer the output of the switched-capacitor filter circuit in order to drive a desired load circuit.

### FIELD

This disclosure relates to the field of integrated circuit implementation and, more particularly, to the implementation of filter circuits.

### BACKGROUND

Communication systems typically include multiple integrated circuits that can send and receive signals between themselves. Signals may be transmitted and received via wires, cables, or other suitable conductors. Alternatively, signals may be transmitted and received wirelessly.

Transmitted signals are subject to a variety of noise sources which can degrade the fidelity of the signals. Wireless signals can be degraded by interactions with other wireless signals, changes in the medium through which the signals are propagating, and the like. Such degradation can make decoding such signals difficult, possibly resulting in a loss of encoded information.

Communication systems typically employ filtering to improve signal quality before decoding the information embedded in the signal. Filtering can attenuate ranges of frequencies that are associated with an undesired signal and/or noise, thereby improving the quality of the desired signal. Filters can be implemented using both active and passive circuit components.

### BRIEF DESCRIPTION OF THE DRAWINGS

FIG. 1 is a block diagram depicting an embodiment of a filter circuit.

FIG. 2 is a block diagram depicting an embodiment of an active pre-filter circuit.

FIG. 3 is a block diagram depicting an embodiment of a passive switched-capacitor filter circuit.

FIG. 4 depicts example waveforms for clock phases used by a passive switched-capacitor filter circuit.

FIG. 5 is a block diagram depicting an embodiment of a passive filter circuit with interleave.

FIG. 6 is a block diagram depicting an embodiment of a receiver circuit.

FIG. 7 is a flow diagram depicting an embodiment of a method for filtering a signal.

FIG. 8 is a block diagram of an embodiment of a device that may include a filter circuit.

FIG. 9 is a block diagram of various embodiments of computer systems that may include filter circuits.

FIG. 10 illustrates an example of a non-transitory computer-readable storage medium that stores circuit design information.

### DETAILED DESCRIPTION

Many computer systems employ wireless communication systems to exchange data with other computer systems. For example, a mobile computer system, e.g., a cellular phone or tablet, may connect to a wireless cellular network to send and receive information. Such mobile computer systems can also employ WiFi or other wireless network technology to connect to a variety of computer systems.

In wireless communication systems, anti-aliasing filters are often employed prior to an analog-to-digital converter stage. Such filters help remove out-of-band signals (often referred to as “blockers”) which can be aliased back to the band of interest during the analog-to-digital conversion.

In wideband receivers, Nyquist-rate analog-to-digital converter circuits with a limited, or in some cases, no oversampling ratio may be used for power consumption reasons. In such cases, the combination of a flat passband response and selectivity requirements with respect to adjacent channels can need complex poles in the transfer function of a filter circuit.

For instance, a third-order filter may be implemented using a Tow-Thomas biquad as the filter core, followed by a first-order stage. Such a solution, however, can consume large amounts of power since three amplifier circuits are employed. Moreover, such a solution does not scale well as higher order filters require additional amplifier circuits.

Another technique involves the use of a transconductance stage that converts the input voltage to current that is dumped into a hold capacitor. The output signal is then sampled and integrated in the charge domain. The sampling and integration operations are performed in consecutive phases to realize real poles, which can result in a slow filter response transition from the passband to the stopband in the frequency domain.

A similar technique can be used to implement discrete-time feedback by preserving a history of the signal charge in a sampling capacitor, which results in complex poles. Such complex poles can sharpen the near-band signal transfer function of the filter circuit. In such implementations, the feedback factor is fixed, and the quality factor is limited (e.g., Q≈ 0.7) and tied to the filter bandwidth since it is determined by a ratio of the geometric mean to the arithmetic mean of the integration capacitors.

The embodiments illustrated in the drawings and described below provide techniques for creating complex poles in a filter transfer function. By employing a hybrid architecture that combines a discrete-time (DT) core with continuous-time (CT) feedback to take advantage of the benefits of both techniques, the power consumption of a filter circuit can be reduced. Moreover, since the signal processing is performed in the voltage domain without using a front-end transconductance-capacitor stage, design issues such as non-linearity and limited bandwidth scaling can be avoided.

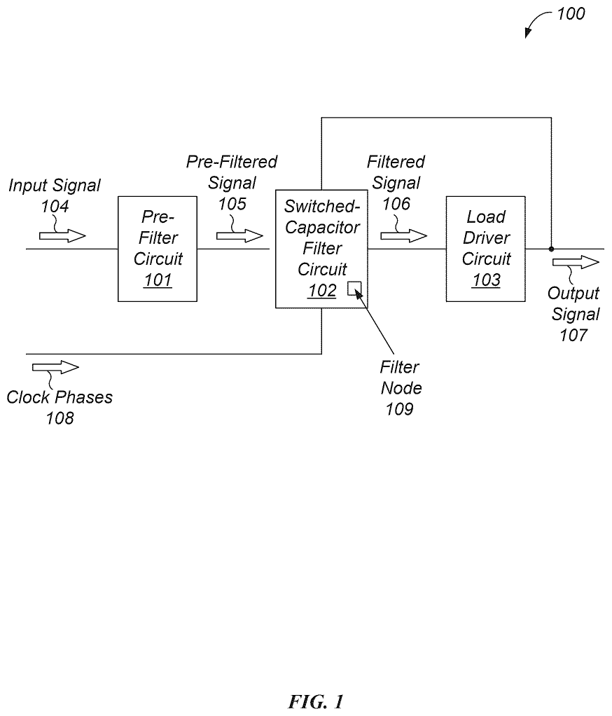

A block diagram of a filter circuit is depicted in FIG. 1. As illustrated, filter circuit 100 includes pre-filter circuit 101, switched-capacitor filter circuit 102, and load driver circuit 103.

Pre-filter circuit 101 is configured to filter input signal 104 to generate pre-filtered signal 105. As described below, pre-filter circuit 101 may be an active filter that includes an amplifier circuit and one or more passive circuit elements, e.g., resistors and capacitors. In various embodiments, the use of pre-filter circuit 101 may allow for the suppression of high-frequency blocker signals near a sampling frequency of switched-capacitor filter circuit 102. Additionally, pre-filter circuit 101 may be configured to provide tunable gain.

Switched-capacitor filter circuit 102 is configured to generate filtered signal 106 using pre-filtered signal 105 and clock phases 108. In various embodiments, clock phases 108 include multiple non-overlapping clock signals that determine multiple time periods during which switched-capacitor filter circuit 102 performs various functions. As described below, switched-capacitor filter circuit 102 may include multiple switches and capacitors that do not consume any static power. Additionally, switched-capacitor filter circuit 102 may implement a complex pole in the transfer function of filter circuit 100, and may provide much of the filter rejection of filter circuit 100.

To generate filtered signal 106, switched-capacitor filter circuit 102 is configured to couple pre-filtered signal 105 to filter node 109 during a first time period, wherein the filter node 109 is coupled to a ground supply node via a first capacitor, and couple a second capacitor between filter node 109 and a ground supply node during a second time period subsequent to the first time period.

Switched-capacitor filter circuit 102 is further configured to couple output signal 107 to filter node 109 via a third capacitor during the second time period, and to couple a fourth capacitor between filter node 109 and the ground supply node during a third time period subsequent to the second time period.

Load driver circuit 103 is configured to generate output signal 107 using filtered signal 106. In various embodiments, filtered signal 106 may correspond to a voltage level across the different filter capacitors included in switched-capacitor filter circuit 102. In different embodiments, load driver circuit 103 may be employed to drive a load impedance, e.g., an analog-to-digital converter circuit. In some embodiments, load driver circuit 103 may be implemented using a buffer circuit or any suitable unity-gain amplifier circuit.

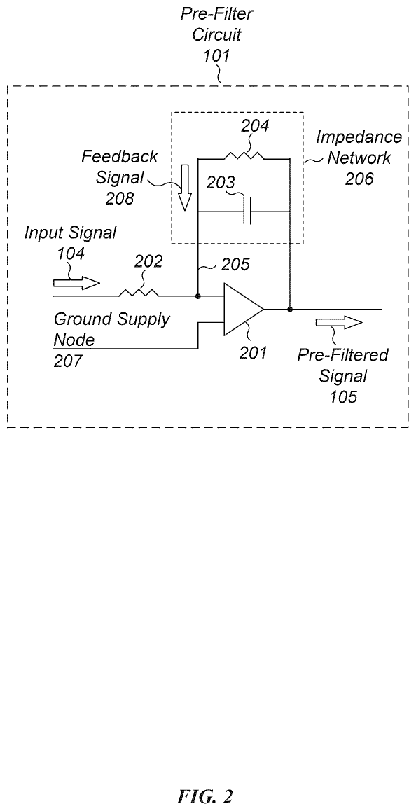

Turning to FIG. 2, a block diagram of an embodiment of pre-filter circuit 101 is depicted. As illustrated, pre-filter circuit 101 includes amplifier circuit 201, resistor 202, and impedance network 206 which includes capacitor 203 and resistor 204.

Amplifier circuit 201 is configured to receive, at a first input, input signal via resistor 202, and amplify a combination of input signal 104 and feedback signal 208 to generate pre-filtered signal 105. In some embodiments, a second input of amplifier circuit 201 is coupled to ground supply node 207. In various embodiments, a gain of amplifier circuit may be set based on respective values of resistor 202 and 204.

In other embodiments, amplifier circuit 201 is also configured to filter input signal 104 to generate pre-filtered signal 105. In some cases, amplifier circuit 201, in conjunction with impedance network 206, may be configured to perform a low-pass filter operation with a cutoff frequency determined by respective values of resistor 204 and capacitor 203. In various embodiments, impedance network 206 generates feedback signal 208 on node 205, which is coupled to resistor 202 and an input of amplifier circuit 201.

Amplifier circuit 201 may be implemented as an operational amplifier circuit, a differential amplifier circuit, or any other suitable amplifier circuit. Resistors 202 and 204 may be implemented using polysilicon, aluminum, or any other suitable material available in a semiconductor manufacturing process. Capacitor 203 may be implemented using a metal-oxide-metal (MOM) capacitor structure, a metal-insulator-metal (MIM) structure, or any other suitable capacitor structure available in a semiconductor manufacturing process.

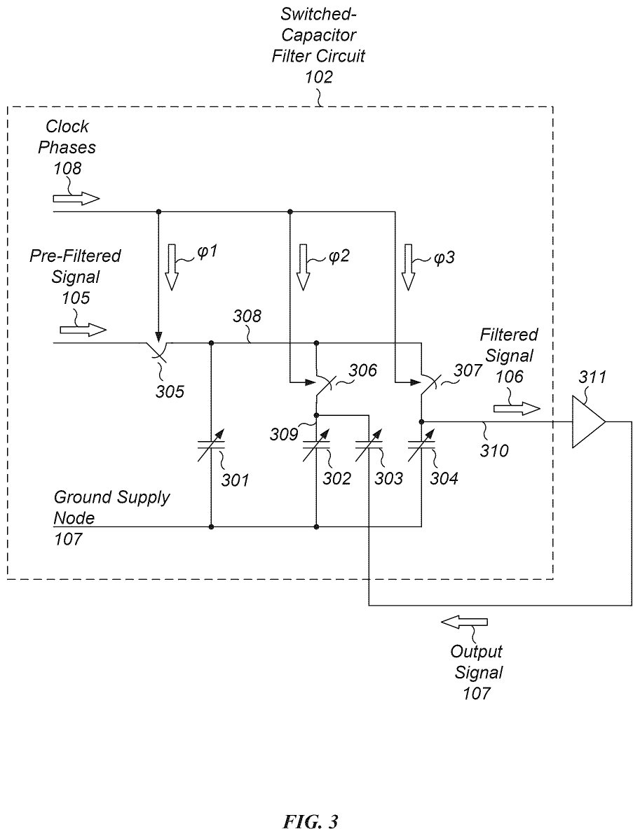

Turning to FIG. 3, a block diagram of an embodiment of switched-capacitor filter circuit 102 is depicted. As illustrated, switched-capacitor filter circuit 102 includes capacitors 301-304 and switches 305-307. In various embodiments, switched-capacitor filter circuit 102 corresponds to a passive biquad which can be used as a building block to create higher order filter circuits.

Switch 305 is configured, in response to an activation of clock phase φ1, to couple pre-filtered signal 105 to node 308 (also referred to as a “filter node”), which is coupled to ground supply node 207 via capacitor 301. When clock phase φ1 is deactivated, switch 305 opens and pre-filtered signal 105 is decoupled from node 308.

Switch 306 is configured, in response to an activation of clock phase φ2, to couple node 309 to node 308, which is coupled to ground supply node 207 via capacitor 302. Node 309 is additionally coupled, via capacitor 303, to output signal 107 generated by buffer circuit 311 (shown for reference). In various embodiments, buffer circuit 311 may correspond to load driver circuit 103. When clock phase φ2 is deactivated, switch 306 opens and node 309 is decoupled from node 308.

Switch 307 is configured, in response to an activation of clock phase φ3 to couple node 308 to node 310, which is coupled to ground supply node 207 via capacitor 304. In various embodiments, a voltage level across capacitor 304 corresponds to filtered signal 106. When clock phase φ3 is deactivated, switch 307 opens and node 310 is decoupled from node 308.

In various embodiments, the feedback factor of switched-capacitor filter circuit 102 is dependent on a ratio of capacitors 302 and 303 as depicted in equation 1, where β is the feedback factor, C₃₀₂ is the value of capacitor 302 and C₃₀₃ is the value of capacitor 303.

$$β = \frac{{C}_{303}}{{C}_{302} + {C}_{303}} \qquad ( 1 )$$

Additionally, using the CT mapping and approximation, the natural frequency and the quality factor of switched-capacitor filter circuit 102 can be determined according to equations 2 and 3, respectively, where ωₙ is the natural frequency, Q is quality factor, C₃₀₁ is the value of capacitor 301, C₃₀₂ is the value of capacitor 302, C₃₀₄ is the value of capacitor 304, and f_{φ1} is the frequency of clock phase 1.

$${ω}_{n} \approx \frac{{C}_{301} {f}_{φ1}}{\sqrt{( {C}_{302} + {C}_{303} ) {C}_{304}}} \qquad ( 2 )$$

$$Q \approx \frac{\sqrt{( {C}_{302} + {C}_{303} ) {C}_{304}}}{{C}_{304} + ( 1 - β ) {C}_{302}} \qquad ( 3 )$$

The bandwidth of switched-capacitor filter circuit 102 may be scaled using the sampling frequency f_{φ1} as shown in equation 2. Moreover, as shown in equation 3, the quality factor of switched-capacitor filter circuit 102 can be controlled by β and a ratio of the value of capacitor 302 to the value of capacitor 304, which provides additional degrees of freedom for switched-capacitor filter circuit 102. It is worth mentioning that since the Barkhuasen oscillation condition is not fulfilled in this circuits, it is stable.

The sub-assembly consisting of switch 306, and capacitors 302 and 303 can be referred to as an integration branch. The order of a switched-capacitor filter circuit, e.g., switched-capacitor filter circuit 102, can be increased by adding more integration branches driven by corresponding clock phases. For example, an n^{th} order filter can be realized using n phases, driving corresponding integration branches. In such cases, each of the n phases has a Tₛ/n duty cycle, where Tₛ is the sampling period

Capacitors 301-304 may, in various embodiments, be implemented using MOM capacitor structures, MIM capacitor structures, or any other suitable capacitor structure available on a semiconductor manufacturing process. It is noted that respective values of capacitors 301-304 may be programmable.

Although the embodiment of FIG. 3 is depicted as filtering a single-ended signal, i.e., pre-filtered signal 105, in other embodiments, switched-capacitor filter circuit 102 may be configured to filter differential signals. Various circuit modifications may be employed to filter differential signals. For example, in some embodiments, capacitor 301 may be used to sample both signals included in a differential signal.

Switches 305-307 may be implemented using one or more transistors or switching devices. In various embodiments, such transistors or switching devices may include n-channel and p-channel metal-oxide field-effect transistors (MOSFETs), Fin field-effect transistors (FinFETs), gate-all-around field-effect transistors (GAAFETs), or any other suitable transistors or switching devices.

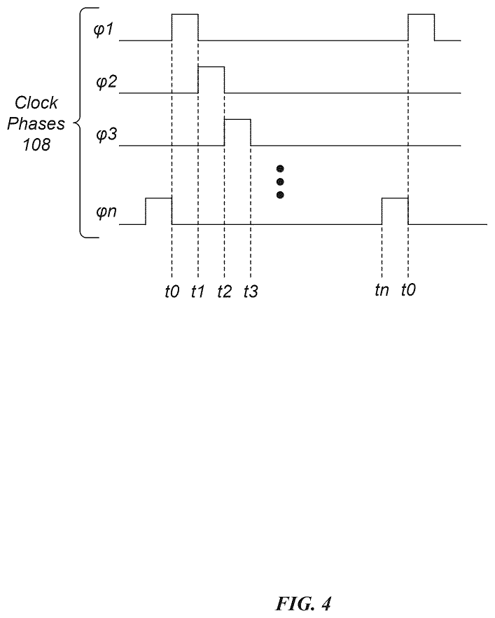

Turning to FIG. 4, a diagram depicting example waveforms for clock phases used by a passive switched-capacitor filter circuit is illustrated. In various embodiments, the clock phases depicted in FIG. 1, may be used with any suitable switched-capacitor filter circuit, e.g., switched-capacitor filter circuit 102. It is noted that although only four clock phases are depicted in the embodiment of FIG. 4, in other embodiments, any suitable number of clock phases may be employed.

At time t0, clock phase φ1 of clock phases 108 is activated and remains active until time t1, at which point clock phase φ1 is deactivated. Additionally, at time t1, clock phase φ2 of clock phases 108 is activated and remains active until time t2.

At time t2, clock phase φ2 is deactivated and clock phase 43 of clock phases 108 is activated. Clock phase 43 remains active until time t3. The sequence of activating clock phases continues until a final clock phase φn is activated at time tn. Clock phase φn is deactivated at time t0 as the cycle then repeats itself.

As described above, some switched-capacitor filter circuits, such as switched-capacitor filter circuit 102, can be generalized to n^{th} order filter. For example, a filter of order n−1 can be created by employing n phases, each with a Tₛ/n duty cycle, where Tₛ is the sampling period. Moreover, n slices can be interleaved, which can increase the oversampling ratio n times and, therefore, can relax the anti-aliasing pre-filtering requirement by pushing the sampling rate to higher frequencies.

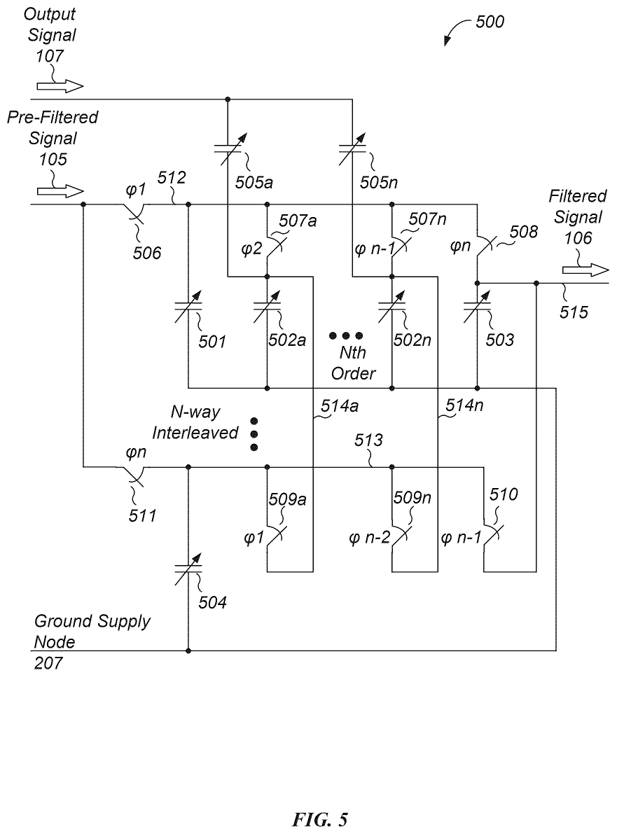

A block diagram of an n^{th} order n-way interleaved switched-capacitor filter circuit is depicted in FIG. 5. As illustrated, switched-capacitor filter circuit 500 includes capacitors 501-504 and 505a-505n, and switches 506-511.

Switch 506 is configured, in response to an activation of clock phase φ1, to couple pre-filtered signal 105 to node 512, which is coupled to ground supply node 207 via capacitor 501. When clock phase φ1 is deactivated, switch 506 opens and pre-filtered signal 105 is decoupled from node 512.

In a similar fashion, switch 511 is configured, in response to an activation of clock phase on, to couple pre-filtered signal 105 to node 513, which is coupled to ground supply node 207 via capacitor 504. When clock phase φn is deactivated, switch 511 opens and pre-filtered signal 105 is decoupled from node 513.

Switch 507a is configured, in response to an activation of clock phase φ2, to couple node 514 to node 512, which is coupled to ground supply node 207 via capacitor 502a. Node 514a is additionally coupled to output signal 107 via capacitor 505a. When clock phase φ2 is deactivated, switch 507a opens and node 514a is decoupled from node 512.

In a similar fashion, switch 509a is configured, in response to an activation of clock phase φ1 to couple node 514a to node 513. When clock phase φ1 is deactivated, switch 509a opens and node 514a is decoupled from node 513.

Switch 507n is configured, in response to an activation of clock phase φn−1, to couple node 514n to node 512, which is coupled to ground supply node 207 via capacitor 502n. Node 514n is additionally coupled to output signal 107 via capacitor 505n. When clock phase φn−1 is deactivated, switch 507n opens and node 514n is decoupled from node 512.

Switch 509n is configured, in response to an activation of clock phase φn−2 to couple node 514n to node 513. When clock phase φn−2 is deactivated, switch 509n opens and node 514n is decoupled from node 513.

It is noted that other integration branches between the 1st integration, consisting of capacitors 502a and 505a, switches 507a and 509b, and the n^{th} integration branch, consisting of capacitors 502n and 505n, and switches 507a and 509b, would operate using respective clock phases of clock phases φ1 to φn.

Switch 508 is configured, in response to an activation of clock phase on to couple node 512 to node 515, which is coupled to ground supply node 207 via capacitor 503. In various embodiments, a voltage level across capacitor 503 corresponds to filtered signal 106. When clock phase on is deactivated, switch 508 opens and node 512 is decoupled from node 515.

In a similar fashion, switch 510 is configured, in response to an activation of clock phase φn−1, to couple node 513 to node 515. When clock phase φn−1 is deactivated, switch 510 opens and node 513 is decoupled from node 515.

For a same noise density, the interleaved arrangement depicted in FIG. 5, allows for a reduction in a size of a sampling capacitor, e.g., capacitor 501, by n times. Using multiple smaller capacitors that are coupled to pre-filter signal 105 at different times can reduce a slew-rate specification for pre-filtered circuit 101. Consequently, switched-capacitor filter circuit 102 along with pre-filter circuit 101 form an n^{th} order filter circuit. It is noted that such a filter circuit has hybrid continuous-time feedback and a discrete-time core. The continuous-time feedback may, in some embodiments, reduce additional switching load on load driver circuit 103 that could be caused by a discrete-time feedback path.

Capacitors 501-505 may, in various embodiments, be implemented using MOM capacitor structures, MIM capacitor structures, or any other suitable capacitor structure available on a semiconductor manufacturing process. It is noted that respective values of capacitors 501-505 may be programmable.

Although the embodiment of FIG. 5 is depicted as filtering a single-ended signal, i.e., pre-filtered signal 105, in other embodiments, switched-capacitor filter circuit 500 may be configured to filter differential signals. Various circuit modifications may be employed to filter differential signals. For example, in some embodiments, capacitor 501 and capacitor 504 may be used to sample both signals included in a differential signal.

Switches 506-511 may be implemented using one or more transistors or switching devices. In various embodiments, such transistors or switching devices may include n-channel and p-channel MOSFETs, FinFETs, GAAFETs, or any other suitable transistors or switching devices.

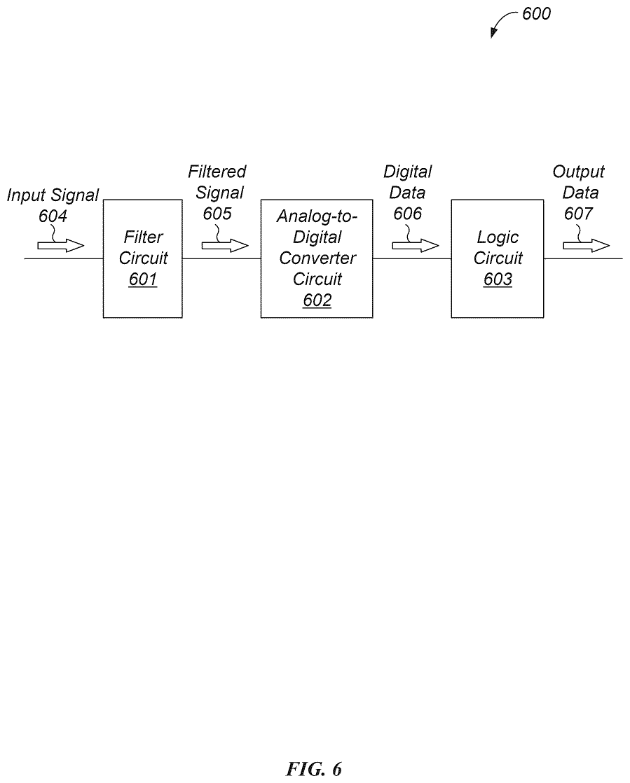

Turning to FIG. 6, a block diagram depicting an embodiment of a receiver circuit is depicted. As illustrated, receiver circuit 600 includes filter circuit 601, analog-to-digital converter circuit 602, and logic circuit 603.

Filter circuit 601 is configured to generate filtered signal 605 using input signal 604. In various embodiments, filter circuit 601 may correspond to filter circuit 100 as depicted in FIG. 1, and may perform any or all of the operations described above. In some embodiments, input signal 604 may be received via a wire, cable, or other suitable conductor. In other embodiments, input signal 604 may be wirelessly received by an antenna coupled to an input of filter circuit 601.

Analog-to-digital converter circuit 602 is configured to generate digital data 606 using filtered signal 605. To generate digital data 606, analog-to-digital converter circuit 602 may be further configured to sample filtered signal 605 at multiple time points, and translate the corresponding samples to digital words whose values correspond to a magnitude of filtered signal 605 at the multiple time points. In various embodiments, analog-to-digital converter circuit 602 may be implemented as a flash analog-to-digital converter circuit, or any other suitable type of analog-to-digital converter circuit.

Logic circuit 603 is configured to generate output data 607 using digital data 606. To generate output data 607, logic circuit 603 may be configured to perform one or more digital signal processing operations on digital data 606. For example, logic circuit 603 may be configured to perform a finite impulse response filter operation, an infinite impulse response filter operation, or any other suitable digital signal processing operation. In various embodiments, logic circuit 603 may be implemented using any suitable combination of sequential and combinatorial logic circuits. For example, logic circuit 603 may be implemented using a processor circuit or a microcontroller circuit.

To summarize, various embodiments of a filter circuit are disclosed. Broadly speaking, the filter circuit includes a pre-filter circuit, a switched-capacitor filter circuit, and a buffer circuit. The pre-filter circuit may be configured to filter an input signal to generate a pre-filtered signal. The switched-capacitor filter circuit may be configured to couple the pre-filtered signal to a first filter node during a first time period, wherein the first filter node is coupled to a ground supply node via a first capacitor, and couple a second capacitor between the first filter node and a ground supply node during a second time period subsequent to the first time period. Additionally, the switched-capacitor filter circuit may be further configured to couple an output signal to the first filter node via a third capacitor during the second time period, and couple a fourth capacitor between the first filter node and the ground supply node during a third time period subsequent to the second time period. The buffer circuit may be configured to generate the output signal using a voltage level across the fourth capacitor.

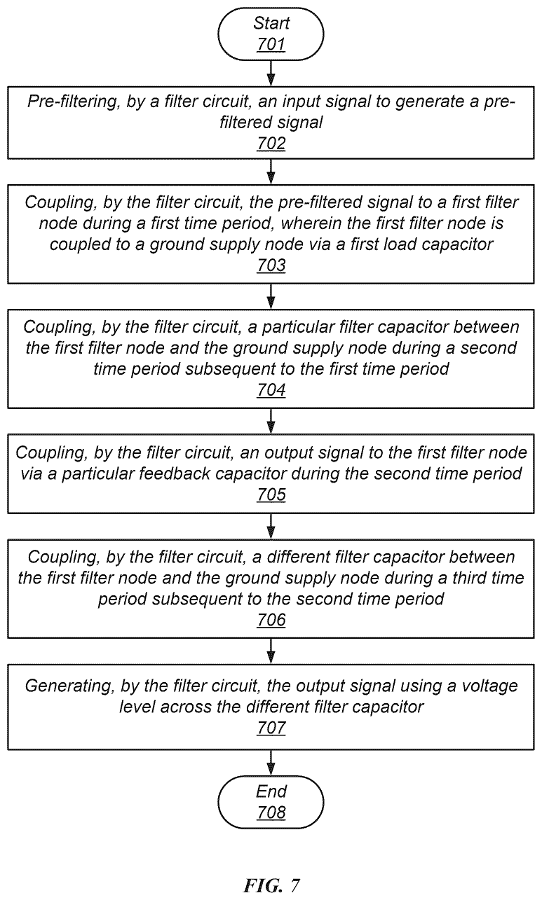

Turning to FIG. 7, a flow diagram of an embodiment of a method for filtering a signal is disclosed. The method, which may be applied to various filter circuits, e.g., filter circuit 100 as depicted in FIG. 1, begins in block 701.

The method includes pre-filtering, by a filter circuit, an input signal to generate a pre-filtered signal (block 702). In various embodiments, pre-filtering the input signal includes generating a feedback signal using an impedance network coupled between an input of an amplifier circuit and an output of the amplifier circuit. In some embodiments, the impedance network includes at least a first resistor and a fifth capacitor. In some cases, the first resistor and the feedback capacitor may be coupled together in series. In other embodiments, generating the pre-filtered signal includes amplifying the input signal.

The method also includes coupling, by the filter circuit, the pre-filtered signal to a first filter node during a first time period (block 703). In various embodiments, the first filter node is coupled to a ground supply node via a first capacitor. In various embodiments, a value of the first capacitor is programmable.

The method further includes coupling, by the filter circuit, a second capacitor between the first filter node and the ground supply node during a second time period subsequent to the first time period (block 704). In various embodiments, a value of the second capacitor is programmable.

The method also includes coupling, by the filter circuit, an output signal to the first filter node via a third capacitor during the second time period (block 705). In various embodiments, a value of the third capacitor is programmable.

The method further includes coupling, by the filter circuit, a fourth capacitor between the first filter node and the ground supply node during a third time period subsequent to the second time period (block 706).

The method also includes generating, by the filter circuit, the output signal using a voltage level across the fourth capacitor (block 707). In various embodiments, generating the output signal includes buffering, by a buffer circuit included in the filter circuit, the voltage level across the fourth capacitor to generate the output signal.

In various embodiments, the method may additionally include coupling, by the filter circuit, the pre-filtered signal to a second filter node during the first time period, where the second filter node is coupled to the ground supply node via a sixth capacitor. In such cases, the method may further include coupling, by the filter circuit, the second capacitor between the second filter node and the ground supply node during the first time period. The method may also include coupling, by the filter circuit, the output signal to the second filter node via the third capacitor during the first time period, and coupling, by the filter circuit, the fourth capacitor between the second filter node and the ground supply node during a fourth time period subsequent to the third time period.

In some embodiments, the method may further include converting, by an analog-to-digital converter circuit, the output signal to digital data. The method concludes in block 708.

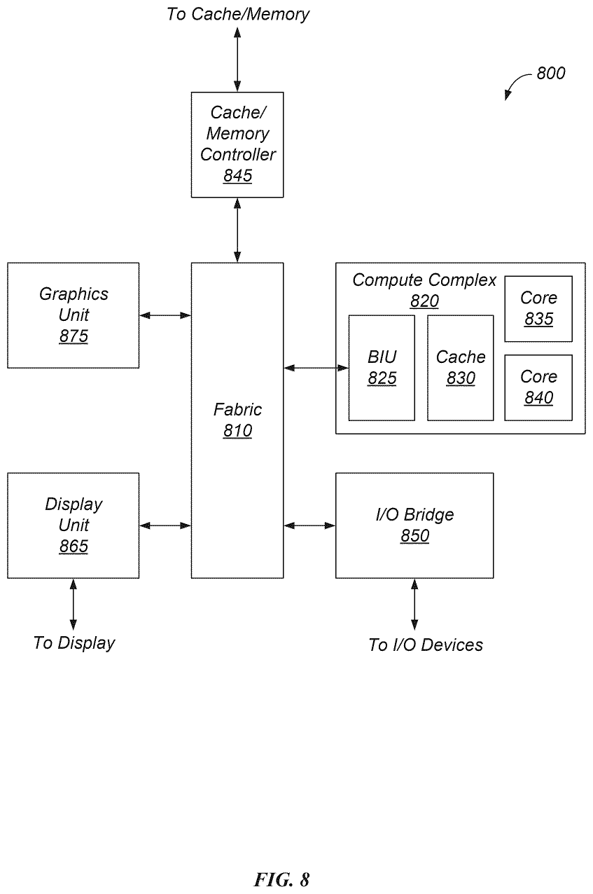

Referring now to FIG. 8, a block diagram illustrating an example embodiment of a device is shown. In some embodiments, elements of device 800 may be included within a system-on-a-chip. In some embodiments, device 800 may be included in a mobile device, which may be battery-powered. Therefore, power consumption by device 800 may be an important design consideration. In the illustrated embodiment, device 800 includes fabric 810, compute complex 820, input/output (I/O) bridge 850, cache/memory controller 845, graphics unit 875, and display unit 865. In some embodiments, device 800 may include other components (not shown) in addition to, or in place of, the illustrated components, such as video processor encoders and decoders, image processing or recognition elements, computer vision elements, etc.

Fabric 810 may include various interconnects, buses, MUX's, controllers, etc., and may be configured to facilitate communication between various elements of device 800. In some embodiments, portions of fabric 810 may be configured to implement various different communication protocols. In other embodiments, fabric 810 may implement a single communication protocol, and elements coupled to fabric 810 may convert from the single communication protocol to other communication protocols internally.

In the illustrated embodiment, compute complex 820 includes bus interface unit (BIU) 825, cache 830, and cores 835 and 840. In various embodiments, compute complex 820 may include various numbers of processors, processor cores, and caches. For example, compute complex 820 may include 1, 2, or 4 processor cores, or any other suitable number. In one embodiment, cache 830 is a set associative L2 cache. In some embodiments, cores 835 and 840 may include internal instruction and data caches. In some embodiments, a coherency unit (not shown) in fabric 810, cache 830, or elsewhere in device 800, may be configured to maintain coherency between various caches of device 800. BIU 825 may be configured to manage communication between compute complex 820 and other elements of device 800. Processor cores, such as cores 835 and 840, may be configured to execute instructions of a particular instruction set architecture (ISA) which may include operating system instructions and user application instructions. These instructions may be stored in a computer readable medium such as a memory coupled to cache/memory controller 845 as discussed below.

As used herein, the term “coupled to” may indicate one or more connections between elements, and a coupling may include intervening elements. For example, in FIG. 8, graphics unit 875 may be described as “coupled to” a memory through fabric 810 and cache/memory controller 845. In contrast, in the illustrated embodiment of FIG. 8, graphics unit 875 is “directly coupled” to fabric 810 because there are no intervening elements.

Cache/memory controller 845 may be configured to manage transfer of data between fabric 810 and one or more caches and memories. For example, cache/memory controller 845 may be coupled to an L3 cache, which may, in turn, be coupled to a system memory. In other embodiments, cache/memory controller 845 may be directly coupled to a memory. In some embodiments, cache/memory controller 845 may include one or more internal caches. Memory coupled to cache/memory controller 845 may be any type of volatile memory, such as dynamic random access memory (DRAM), synchronous DRAM (SDRAM), double data rate (DDR, DDR2, DDR3, etc.) SDRAM (including mobile versions of SDRAMs such as mDDR3, etc., and/or low power versions of SDRAMs such as LPDDR4, etc.), RAMBUS DRAM (RDRAM), static RAM (SRAM), etc. One or more memory devices may be coupled onto a circuit board to form memory modules such as single inline memory modules (SIMMs), dual inline memory modules (DIMMs), etc. Alternatively, the devices may be mounted with an integrated circuit in a chip-on-chip configuration, a package-on-package configuration, or a multi-chip module configuration. Memory coupled to cache/memory controller 845 may be any type of non-volatile memory such as NAND flash memory, NOR flash memory, nano RAM (NRAM), magneto-resistive RAM (MRAM), phase change RAM (PRAM), Racetrack memory, Memristor memory, etc. As noted above, this memory may store program instructions executable by compute complex 820 to cause the computing device to perform functionality described herein.

Graphics unit 875 may include one or more processors, e.g., one or more graphics processing units (GPUs). Graphics unit 875 may receive graphics-oriented instructions, such as OPENGL®, Metal®, or DIRECT3D® instructions, for example. Graphics unit 875 may execute specialized GPU instructions or perform other operations based on the received graphics-oriented instructions. Graphics unit 875 may generally be configured to process large blocks of data in parallel, and may build images in a frame buffer for output to a display, which may be included in the device or may be a separate device. Graphics unit 875 may include transform, lighting, triangle, and rendering engines in one or more graphics processing pipelines. Graphics unit 875 may output pixel information for display images. Graphics unit 875, in various embodiments, may include programmable shader circuitry which may include highly parallel execution cores configured to execute graphics programs, which may include pixel tasks, vertex tasks, and compute tasks (which may or may not be graphics-related).

Display unit 865 may be configured to read data from a frame buffer and provide a stream of pixel values for display. Display unit 865 may be configured as a display pipeline in some embodiments. Additionally, display unit 865 may be configured to blend multiple frames to produce an output frame. Further, display unit 865 may include one or more interfaces (e.g., MIPI® or embedded display port (eDP)) for coupling to a user display (e.g., a touchscreen or an external display).

I/O bridge 850 may include various elements configured to implement universal serial bus (USB) communications, security, audio, and low-power always-on functionality, for example. I/O bridge 850 may also include interfaces such as pulse-width modulation (PWM), general-purpose input/output (GPIO), serial peripheral interface (SPI), and inter-integrated circuit (I2C), for example. Various types of peripherals and devices may be coupled to device 800 via I/O bridge 850.

In some embodiments, device 800 includes network interface circuitry (not explicitly shown), which may be connected to fabric 810 or I/O bridge 850. The network interface circuitry may be configured to communicate via various networks, which may be wired, wireless, or both. For example, the network interface circuitry may be configured to communicate via a wired local area network, a wireless local area network (e.g., via Wi-Fi™), or a wide area network (e.g., the Internet or a virtual private network). In some embodiments, the network interface circuitry is configured to communicate via one or more cellular networks that use one or more radio access technologies. In some embodiments, the network interface circuitry is configured to communicate using device-to-device communications (e.g., Bluetooth® or Wi-Fi™ Direct), etc. In various embodiments, the network interface circuitry may provide device 800 with connectivity to various types of other devices and networks.

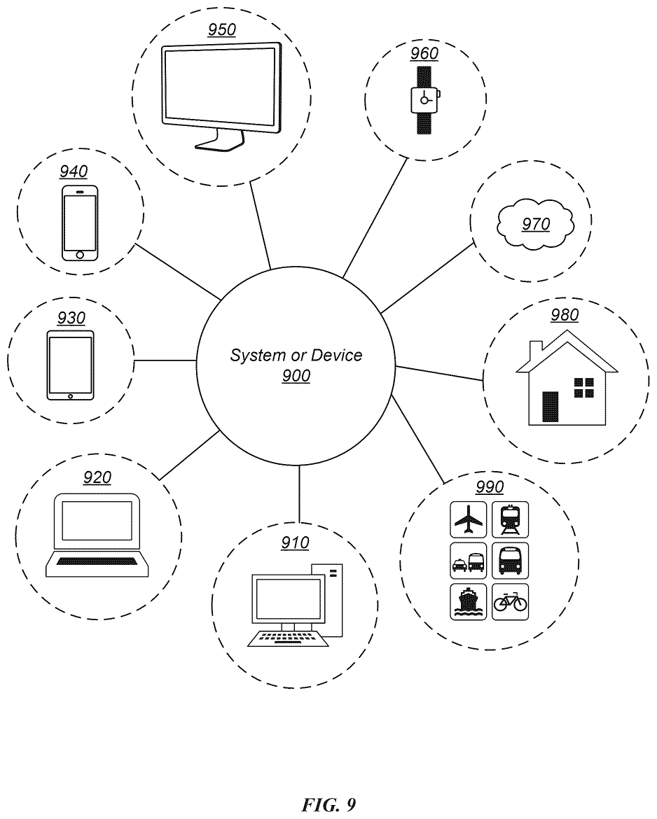

Turning now to FIG. 9, various types of systems that may include any of the circuits, devices, or systems discussed above are illustrated. System or device 900, which may incorporate or otherwise utilize one or more of the techniques described herein, may be utilized in a wide range of areas. For example, system or device 900 may be utilized as part of the hardware of systems such as a desktop computer 910, laptop computer 920, tablet computer 930, cellular or mobile phone 940, or television 950 (or set-top box coupled to a television).

Similarly, disclosed elements may be utilized in a wearable device 960, such as a smartwatch or a health-monitoring device. Smartwatches, in many embodiments, may implement a variety of different functions—for example, access to email, cellular service, calendar, health monitoring, etc. A wearable device may also be designed solely to perform health-monitoring functions, such as monitoring a user's vital signs, performing epidemiological functions such as contact tracing, providing communication to an emergency medical service, etc. Other types of devices are also contemplated, including devices worn on the neck, devices implantable in the human body, glasses or a helmet designed to provide computer-generated reality experiences such as those based on augmented and/or virtual reality, etc.

System or device 900 may also be used in various other contexts. For example, system or device 900 may be utilized in the context of a server computer system, such as a dedicated server or on shared hardware that implements a cloud-based service 970. Still further, system or device 900 may be implemented in a wide range of specialized everyday devices, including devices 980 commonly found in the home such as refrigerators, thermostats, security cameras, etc. The interconnection of such devices is often referred to as the “Internet of Things” (IoT). Elements may also be implemented in various modes of transportation. For example, system or device 900 could be employed in the control systems, guidance systems, entertainment systems, etc. of various types of vehicles 990.

The applications illustrated in FIG. 9 are merely exemplary and are not intended to limit the potential future applications of disclosed systems or devices. Other example applications include, without limitation: portable gaming devices, music players, data storage devices, unmanned aerial vehicles, etc.

The present disclosure has described various example circuits in detail above. It is intended that the present disclosure cover not only embodiments that include such circuitry, but also a computer-readable storage medium that includes design information that specifies such circuitry. Accordingly, the present disclosure is intended to support claims that cover not only an apparatus that includes the disclosed circuitry, but also a storage medium that specifies the circuitry in a format that programs a computing system to generate a simulation model of the hardware circuit, programs a fabrication system configured to produce hardware (e.g., an integrated circuit) that includes the disclosed circuitry, etc. Claims to such a storage medium are intended to cover, for example, an entity that produces a circuit design, but does not itself perform complete operations such as design simulation, design synthesis, circuit fabrication, etc.

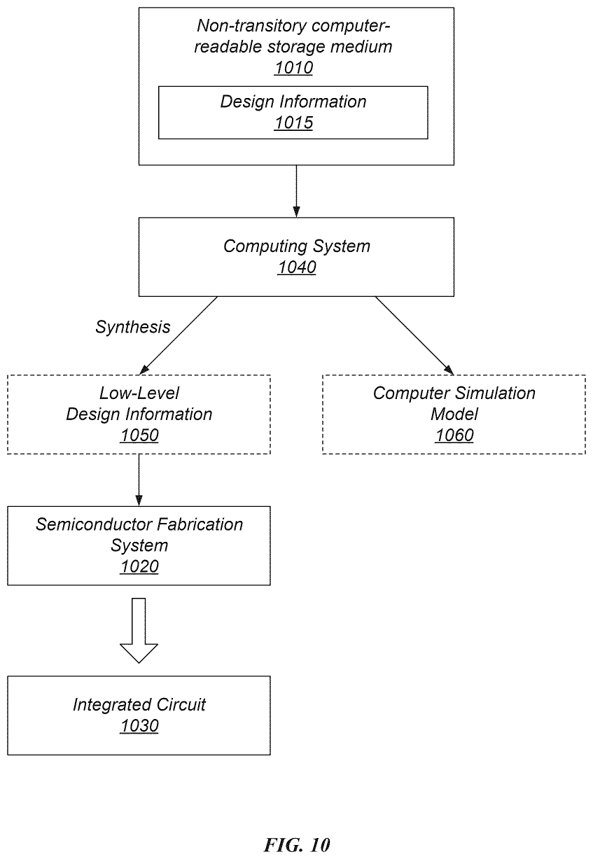

FIG. 10 is a block diagram illustrating an example of a non-transitory computer-readable storage medium that stores design information 1015, according to some embodiments. In the illustrated embodiment, computing system 1040 is configured to process design information 1015. This may include executing instructions included in design information 1015, interpreting instructions included in design information 1015, compiling, transforming, or otherwise updating design information 1015, etc. Therefore, design information 1015 controls computing system 1040 (e.g., by programming computing system 1040) to perform various operations discussed below, in some embodiments.

In the illustrated example, computing system 1040 processes design information 1015 to generate both computer simulation model of hardware circuit 1060 and low-level design information 1050. In other embodiments, computing system 1040 may generate only one of these outputs, may generate other outputs based on design information 1015, or both. Regarding computer simulation model of hardware circuit 1060, computing system 1040 may execute instructions of a hardware description language that includes register transfer level (RTL) code, behavioral code, structural code, or some combination thereof. The simulation model may perform the functionality specified by design information 1015, facilitate verification of the functional correctness of the hardware design, generate power consumption estimates, generate timing estimates, etc.

In the illustrated example, computing system 1040 also processes design information 1015 to generate low-level design information 1050 (e.g., gate-level design information, a netlist, etc.). This may include synthesis operations, as shown, such as constructing a multi-level network, optimizing the network using technology-independent techniques, technology dependent techniques, or both, and outputting a network of gates (with potential constraints based on available gates in a technology library, sizing, delay, power, etc.). Based on low-level design information 1050 (potentially among other inputs), semiconductor fabrication system 1020 is configured to fabricate integrated circuit 1030 (which may correspond to functionality of the computer simulation model of hardware circuit 1060). Note that computing system 1040 may generate different simulation models based on design information at various levels of description, including low-level design information 1050, design information 1015, and so on. The data representing low-level design information 1050 and computer simulation model of hardware circuit 1060 may be stored on non-transitory computer-readable storage medium 1010, or on one or more other media.

In some embodiments, low-level design information 1050 controls (e.g., programs) semiconductor fabrication system 1020 to fabricate integrated circuit 1030. Thus, when processed by the fabrication system, the design information may program the fabrication system to fabricate a circuit that includes various circuitry disclosed herein.

Non-transitory computer-readable storage medium 1010 may comprise any of various appropriate types of memory devices or storage devices. Non-transitory computer-readable storage medium 1010 may be an installation medium, e.g., a CD-ROM, floppy disks, or tape device; a computer system memory or random access memory such as DRAM, DDR RAM, SRAM, EDO RAM, Rambus RAM, etc.; a non-volatile memory such as a Flash memory, magnetic media, e.g., a hard drive, or optical storage; registers, or other similar types of memory elements, etc. Non-transitory computer-readable storage medium 1010 may include other types of non-transitory memory as well, or combinations thereof. Accordingly, non-transitory computer-readable storage medium 1010 may include two or more memory media, which may reside in different locations—for example, in different computer systems that are connected over a network.

Design information 1015 may be specified using any of various appropriate computer languages, including hardware description languages such as, without limitation: VHDL, Verilog, SystemC, System Verilog, RHDL, M, MyHDL, etc. The format of various design information may be recognized by one or more applications executed by computing system 1040, semiconductor fabrication system 1020, or both. In some embodiments, design information 1015 may also include one or more cell libraries that specify the synthesis, layout, or both of integrated circuit 1030. In some embodiments, design information 1015 is specified in whole, or in part, in the form of a netlist that specifies cell library elements and their connectivity. Design information discussed herein, taken alone, may or may not include sufficient information for fabrication of a corresponding integrated circuit. For example, design information may specify the circuit elements to be fabricated but not their physical layout. In this case, design information may be combined with layout information to actually fabricate the specified circuitry.

Integrated circuit 1030 may, in various embodiments, include one or more custom macrocells, such as memories, analog or mixed-signal circuits, and the like. In such cases, design information 1015 may include information related to included macrocells. Such information may include, without limitation, schematics capture database, mask design data, behavioral models, and device or transistor level netlists. Mask design data may be formatted according to graphic data system (GDSII), or any other suitable format.

Semiconductor fabrication system 1020 may include any of various appropriate elements configured to fabricate integrated circuits. This may include, for example, elements for depositing semiconductor materials (e.g., on a wafer, which may include masking), removing materials, altering the shape of deposited materials, modifying materials (e.g., by doping materials or modifying dielectric constants using ultraviolet processing), etc. Semiconductor fabrication system 1020 may also be configured to perform various testing of fabricated circuits for correct operation.

In various embodiments, integrated circuit 1030 and computer simulation model of hardware circuit 1060 are configured to operate according to a circuit design specified by design information 1015, which may include performing any of the functionality described herein. For example, integrated circuit 1030 may include any of various elements shown in FIGS. 1-6. Further, integrated circuit 1030 may be configured to perform various functions described herein in conjunction with other components. Further, the functionality described herein may be performed by multiple connected integrated circuits.

As used herein, a phrase of the form “design information that specifies a design of a circuit configured to . . . ” does not imply that the circuit in question must be fabricated in order for the element to be met. Rather, this phrase indicates that the design information describes a circuit that, upon being fabricated, will be configured to perform the indicated actions or will include the specified components. Similarly, stating “instructions of a hardware description programming language” that are “executable” to program a computing system to generate a computer simulation model does not imply that the instructions must be executed in order for the element to be met, but rather, specifies characteristics of the instructions. Additional features relating to the model (or the circuit represented by the model) may similarly relate to characteristics of the instructions, in this context. Therefore, an entity that sells a computer-readable medium with instructions that satisfy recited characteristics may provide an infringing product, even if another entity actually executes the instructions on the medium.

Note that a given design, at least in the digital logic context, may be implemented using a multitude of different gate arrangements, circuit technologies, etc. As one example, different designs may select or connect gates based on design tradeoffs (e.g., to focus on power consumption, performance, circuit area, etc.). Further, different manufacturers may have proprietary libraries, gate designs, physical gate implementations, etc. Different entities may also use different tools to process design information at various layers (e.g., from behavioral specifications to physical layout of gates).

Once a digital logic design is specified, however, those skilled in the art need not perform substantial experimentation or research to determine those implementations. Rather, those of skill in the art understand procedures to reliably and predictably produce one or more circuit implementations that provide the function described by design information 1015. The different circuit implementations may affect the performance, area, power consumption, etc. of a given design (potentially with tradeoffs between different design goals), but the logical function does not vary among the different circuit implementations of the same circuit design.

In some embodiments, the instructions included in design information 1015 provide RTL information (or other higher-level design information) and are executable by the computing system to synthesize a gate-level netlist that represents the hardware circuit based on the RTL information as an input. Similarly, the instructions may provide behavioral information and be executable by the computing system to synthesize a netlist or other lower-level design information included in low-level design information 1050. Low-level design information 1050 may program semiconductor fabrication system 1020 to fabricate integrated circuit 1030.

The present disclosure includes references to an “embodiment” or groups of “embodiments” (e.g., “some embodiments” or “various embodiments”). Embodiments are different implementations or instances of the disclosed concepts. References to “an embodiment,” “one embodiment,” “a particular embodiment,” and the like do not necessarily refer to the same embodiment. A large number of possible embodiments are contemplated, including those specifically disclosed, as well as modifications or alternatives that fall within the spirit or scope of the disclosure.

This disclosure may discuss potential advantages that may arise from the disclosed embodiments. Not all implementations of these embodiments will necessarily manifest any or all of the potential advantages. Whether an advantage is realized for a particular implementation depends on many factors, some of which are outside the scope of this disclosure. In fact, there are a number of reasons why an implementation that falls within the scope of the claims might not exhibit some or all of any disclosed advantages. For example, a particular implementation might include other circuitry outside the scope of the disclosure that, in conjunction with one of the disclosed embodiments, negates or diminishes one or more of the disclosed advantages. Furthermore, suboptimal design execution of a particular implementation (e.g., implementation techniques or tools) could also negate or diminish disclosed advantages. Even assuming a skilled implementation, realization of advantages may still depend upon other factors such as the environmental circumstances in which the implementation is deployed. For example, inputs supplied to a particular implementation may prevent one or more problems addressed in this disclosure from arising on a particular occasion, with the result that the benefit of its solution may not be realized. Given the existence of possible factors external to this disclosure, it is expressly intended that any potential advantages described herein are not to be construed as claim limitations that must be met to demonstrate infringement. Rather, identification of such potential advantages is intended to illustrate the type(s) of improvement available to designers having the benefit of this disclosure. That such advantages are described permissively (e.g., stating that a particular advantage “may arise”) is not intended to convey doubt about whether such advantages can in fact be realized, but rather to recognize the technical reality that realization of such advantages often depends on additional factors.

Unless stated otherwise, embodiments are non-limiting. That is, the disclosed embodiments are not intended to limit the scope of claims that are drafted based on this disclosure, even where only a single example is described with respect to a particular feature. The disclosed embodiments are intended to be illustrative rather than restrictive, absent any statements in the disclosure to the contrary. The application is thus intended to permit claims covering disclosed embodiments, as well as such alternatives, modifications, and equivalents that would be apparent to a person skilled in the art having the benefit of this disclosure.

For example, features in this application may be combined in any suitable manner. Accordingly, new claims may be formulated during prosecution of this application (or an application claiming priority thereto) to any such combination of features. In particular, with reference to the appended claims, features from dependent claims may be combined with those of other dependent claims where appropriate, including claims that depend from other independent claims. Similarly, features from respective independent claims may be combined where appropriate.

Accordingly, while the appended dependent claims may be drafted such that each depends on a single other claim, additional dependencies are also contemplated. Any combinations of features in the dependent claims that are consistent with this disclosure are contemplated and may be claimed in this or another application. In short, combinations are not limited to those specifically enumerated in the appended claims.

Where appropriate, it is also contemplated that claims drafted in one format or statutory type (e.g., apparatus) are intended to support corresponding claims of another format or statutory type (e.g., method).

Because this disclosure is a legal document, various terms and phrases may be subject to administrative and judicial interpretation. Public notice is hereby given that the following paragraphs, as well as definitions provided throughout the disclosure, are to be used in determining how to interpret claims that are drafted based on this disclosure.

References to a singular form of an item (i.e., a noun or noun phrase preceded by “a,” “an,” or “the”) are, unless context clearly dictates otherwise, intended to mean “one or more.” Reference to “an item” in a claim thus does not, without accompanying context, preclude additional instances of the item. A “plurality” of items refers to a set of two or more of the items.

The word “may” is used herein in a permissive sense (i.e., having the potential to, being able to) and not in a mandatory sense (i.e., must).

The terms “comprising” and “including,” and forms thereof, are open-ended and mean ‘including, but not limited to.”

When the term “or” is used in this disclosure with respect to a list of options, it will generally be understood to be used in the inclusive sense unless the context provides otherwise. Thus, a recitation of “x or y” is equivalent to “x or y, or both,” and thus covers 1) x but not y, 2) y but not x, and 3) both x and y. On the other hand, a phrase such as “either x or y, but not both” makes clear that “or” is being used in the exclusive sense.

A recitation of “w, x, y, or z, or any combination thereof” or “at least one of . . . w, x, y, and z” is intended to cover all possibilities involving a single element up to the total number of elements in the set. For example, given the set [w, x, y, z], these phrasings cover any single element of the set (e.g., w but not x, y, or z), any two elements (e.g., w and x, but not y or z), any three elements (e.g., w, x, and y, but not z), and all four elements. The phrase “at least one of . . . w, x, y, and z” thus refers to at least one element of the set [w, x, y, z], thereby covering all possible combinations in this list of elements. This phrase is not to be interpreted to require that there is at least one instance of w, at least one instance of x, at least one instance of y, and at least one instance of z.

Various “labels” may precede nouns or noun phrases in this disclosure. Unless context provides otherwise, different labels used for a feature (e.g., “first circuit,” “second circuit,” “particular circuit,” “given circuit,” etc.) refer to different instances of the feature. Additionally, the labels “first,” “second,” and “third,” when applied to a feature, do not imply any type of ordering (e.g., spatial, temporal, logical, etc.), unless stated otherwise.

The phrase “based on” is used to describe one or more factors that affect a determination. This term does not foreclose the possibility that additional factors may affect the determination. That is, a determination may be solely based on specified factors, or based on the specified factors as well as other, unspecified factors. Consider the phrase “determine A based on B.” This phrase specifies that B is a factor that is used to determine A or that affects the determination of A. This phrase does not foreclose that the determination of A may also be based on some other factor, such as C. This phrase is also intended to cover an embodiment in which A is determined based solely on B. As used herein, the phrase “based on” is synonymous with the phrase “based at least in part on.”

The phrases “in response to” and “responsive to” describe one or more factors that trigger an effect. This phrase does not foreclose the possibility that additional factors may affect or otherwise trigger the effect, either jointly with the specified factors or independent from the specified factors. That is, an effect may be solely in response to those factors, or may be in response to the specified factors as well as other, unspecified factors. Consider the phrase “perform A in response to B.” This phrase specifies that B is a factor that triggers the performance of A, or that triggers a particular result for A. This phrase does not foreclose that performing A may also be in response to some other factor, such as C. This phrase also does not foreclose that performing A may be jointly in response to B and C. This phrase is also intended to cover an embodiment in which A is performed solely in response to B. As used herein, the phrase “responsive to” is synonymous with the phrase “responsive at least in part to.” Similarly, the phrase “in response to” is synonymous with the phrase “at least in part in response to.”

Within this disclosure, different entities (which may variously be referred to as “units,” “circuits,” other components, etc.) may be described or claimed as “configured” to perform one or more tasks or operations. This formulation—[entity] configured to [perform one or more tasks]—is used herein to refer to structure (i.e., something physical). More specifically, this formulation is used to indicate that this structure is arranged to perform the one or more tasks during operation. A structure can be said to be “configured to” perform some task even if the structure is not currently being operated. Thus, an entity described or recited as being “configured to” perform some task refers to something physical, such as a device, a circuit, or a system having a processor unit and a memory storing program instructions executable to implement the task, etc. This phrase is not used herein to refer to something intangible.

In some cases, various units/circuits/components may be described herein as performing a set of tasks or operations. It is understood that those entities are “configured to” perform those tasks/operations, even if not specifically noted.

The term “configured to” is not intended to mean “configurable to.” An unprogrammed FPGA, for example, would not be considered to be “configured to” perform a particular function. This unprogrammed FPGA may be “configurable to” perform that function, however. After appropriate programming, the FPGA may then be said to be “configured to” perform the particular function.

For purposes of United States patent applications based on this disclosure, reciting in a claim that a structure is “configured to” perform one or more tasks is expressly intended not to invoke 35 U.S.C. § 112(f) for that claim element. Should Applicant wish to invoke Section 112(f) during prosecution of a United States patent application based on this disclosure, it will recite claim elements using the “means for” [performing a function] construct.

Different “circuits” may be described in this disclosure. These circuits or “circuitry” constitute hardware that includes various types of circuit elements, such as combinatorial logic, clocked storage devices (e.g., flip-flops, registers, latches, etc.), finite state machines, memory (e.g., random-access memory, embedded dynamic random-access memory), programmable logic arrays, and so on. Circuitry may be custom designed, or taken from standard libraries. In various implementations, circuitry can, as appropriate, include digital components, analog components, or a combination of both. Certain types of circuits may be commonly referred to as “units” (e.g., a decode unit, an arithmetic logic unit (ALU), a functional unit, a memory management unit (MMU), etc.). Such units also refer to circuits or circuitry.

The disclosed circuits/units/components and other elements illustrated in the drawings and described herein thus include hardware elements such as those described in the preceding paragraph. In many instances, the internal arrangement of hardware elements within a particular circuit may be specified by describing the function of that circuit. For example, a particular “decode unit” may be described as performing the function of “processing an opcode of an instruction and routing that instruction to one or more of a plurality of functional units,” which means that the decode unit is “configured to” perform this function. This specification of function is sufficient, to those skilled in the computer arts, to connote a set of possible structures for the circuit.

In various embodiments, as discussed in the preceding paragraph, circuits, units, and other elements may be defined by the functions or operations that they are configured to implement. The arrangement of such circuits/units/components with respect to each other and the manner in which they interact form a microarchitectural definition of the hardware that is ultimately manufactured in an integrated circuit or programmed into an FPGA to form a physical implementation of the microarchitectural definition. Thus, the microarchitectural definition is recognized by those of skill in the art as a structure from which many physical implementations may be derived, all of which fall into the broader structure described by the microarchitectural definition. That is, a skilled artisan presented with the microarchitectural definition supplied in accordance with this disclosure may, without undue experimentation and with the application of ordinary skill, implement the structure by coding the description of the circuits/units/components in a hardware description language (HDL) such as Verilog or VHDL. The HDL description is often expressed in a fashion that may appear to be functional. But to those of skill in the art in this field, this HDL description is the manner that is used to transform the structure of a circuit, unit, or component to the next level of implementational detail. Such an HDL description may take the form of behavioral code (which is typically not synthesizable), register transfer language (RTL) code (which, in contrast to behavioral code, is typically synthesizable), or structural code (e.g., a netlist specifying logic gates and their connectivity). The HDL description may subsequently be synthesized against a library of cells designed for a given integrated circuit fabrication technology, and may be modified for timing, power, and other reasons to result in a final design database that is transmitted to a foundry to generate masks and ultimately produce the integrated circuit. Some hardware circuits, or portions thereof, may also be custom-designed in a schematic editor and captured into the integrated circuit design along with synthesized circuitry. The integrated circuits may include transistors and other circuit elements (e.g., passive elements such as capacitors, resistors, inductors, etc.) and interconnect between the transistors and circuit elements. Some embodiments may implement multiple integrated circuits coupled together to implement the hardware circuits, and/or discrete elements may be used in some embodiments. Alternatively, the HDL design may be synthesized to a programmable logic array such as a field programmable gate array (FPGA) and may be implemented in the FPGA. This decoupling between the design of a group of circuits and the subsequent low-level implementation of these circuits commonly results in the scenario in which the circuit or logic designer never specifies a particular set of structures for the low-level implementation beyond a description of what the circuit is configured to do, as this process is performed at a different stage of the circuit implementation process.

The fact that many different low-level combinations of circuit elements may be used to implement the same specification of a circuit results in a large number of equivalent structures for that circuit. As noted, these low-level circuit implementations may vary according to changes in the fabrication technology, the foundry selected to manufacture the integrated circuit, the library of cells provided for a particular project, etc. In many cases, the choices made by different design tools or methodologies to produce these different implementations may be arbitrary.

Moreover, it is common for a single implementation of a particular functional specification of a circuit to include, for a given embodiment, a large number of devices (e.g., millions of transistors). Accordingly, the sheer volume of this information makes it impractical to provide a full recitation of the low-level structure used to implement a single embodiment, let alone the vast array of equivalent possible implementations. For this reason, the present disclosure describes structure of circuits using the functional shorthand commonly employed in the industry.

What is claimed is:

1. An apparatus, comprising:
a pre-filter circuit configured to filter an input signal to generate a pre-filtered signal;
a switched-capacitor filter circuit configured to:
couple the pre-filtered signal to a first filter node during a first time period, wherein the first filter node is coupled to a ground supply node via a first capacitor;
couple a second capacitor between the first filter node and a ground supply node during a second time period subsequent to the first time period;
couple an output signal to the first filter node via a third capacitor during the second time period; and
couple a fourth capacitor between the first filter node and the ground supply node during a third time period subsequent to the second time period; and
a buffer circuit configured to generate the output signal using a voltage level across the fourth capacitor.

2. The apparatus of claim 1, wherein the pre-filter circuit includes:
an amplifier circuit configured to amplify a combination of the input signal and a feedback signal to generate the pre-filtered signal; and
an impedance network coupled between an input of the amplifier circuit and an output of the amplifier circuit, and wherein the impedance network is configured to generate the feedback signal using the pre-filtered signal.

3. The apparatus of claim 2, wherein the impedance network includes at least a first resistor and a fifth capacitor.

4. The apparatus of claim 1, wherein the switched-capacitor filter circuit is further configured to:
couple the pre-filtered signal to a second filter node during the first time period, wherein the second filter node is coupled to the ground supply node via a sixth capacitor;
couple the second capacitor between the second filter node and the ground supply node during the first time period;
couple the output signal to the second filter node via the third capacitor during the first time period; and
couple the fourth capacitor between the second filter node and the ground supply node during a fourth time period subsequent to the third time period.

5. The apparatus of claim 1, wherein a value of the first capacitor is programmable.

6. The apparatus of claim 1, wherein a value of the third capacitor is programmable.

7. A method, comprising:
pre-filtering, by a filter circuit, an input signal to generate a pre-filtered signal;
coupling, by the filter circuit, the pre-filtered signal to a first filter node during a first time period, wherein the first filter node is coupled to a ground supply node via a first capacitor;
coupling, by the filter circuit, a second capacitor between the first filter node and the ground supply node during a second time period subsequent to the first time period;
coupling, by the filter circuit, an output signal to the first filter node via a third capacitor during the second time period;
coupling, by the filter circuit, a fourth capacitor between the first filter node and the ground supply node during a third time period subsequent to the second time period; and
generating, by the filter circuit, the output signal using a voltage level across the fourth capacitor.

8. The method of claim 7, wherein pre-filtering the input signal includes:
generating a feedback signal using an impedance network coupled between an output of an amplifier circuit and an input of the amplifier circuit; and
combining the feedback signal with the input signal at the input of the amplifier circuit.

9. The method of claim 8, wherein the impedance network includes at least a first resistor and a fifth capacitor.

10. The method of claim 7, wherein pre-filtering the input signal includes amplifying the input signal.

11. The method of claim 7, further comprising:
coupling, by the filter circuit, the pre-filtered signal to a second filter node during the first time period, wherein the second filter node is coupled to the ground supply node via a sixth capacitor;
coupling, by the filter circuit, the second capacitor between the second filter node and the ground supply node during the first time period;
coupling, by the filter circuit, the output signal to the second filter node via the third capacitor during the first time period; and
coupling, by the filter circuit, the fourth capacitor between the second filter node and the ground supply node during a fourth time period subsequent to the third time period.

12. The method of claim 7, wherein a value of the first capacitor is programmable.

13. The method of claim 7, further comprising converting, by an analog-to-digital converter circuit, the output signal to digital data.

14. A system, comprising:
a filter circuit configured to generate a filtered signal using an input signal;
an analog-to-digital converter circuit configured to generate digital data using the filtered signal; and
a logic circuit configured to generate output data using the digital data; and
wherein to generate the filtered signal, the filter circuit is further configured to:
pre-filter the input signal to generate a pre-filtered signal;
couple the pre-filtered signal to a first filter node during a first time period, wherein the first filter node is coupled to a ground supply node via a first capacitor;
couple a second capacitor between the first filter node and the ground supply node during a second time period subsequent to the first time period;
couple the filtered signal to the first filter node via a third capacitor during the second time period;
couple a fourth capacitor between the first filter node and the ground supply node during a third time period subsequent to the second time period; and
generate the filtered signal using a voltage level across the fourth capacitor.

15. The system of claim 14, wherein to pre-filter the input signal, the filter circuit is further configured to amplify a combination of the input signal and a feedback signal to generate the pre-filtered signal.

16. The system of claim 15, wherein the filter circuit is further configured to generate the feedback signal using an impedance network coupled between the pre-filtered signal and the input signal.

17. The system of claim 16, wherein the impedance network includes at least a first resistor and a fifth capacitor.

18. The system of claim 14, wherein the filter circuit is further configured to:
couple the pre-filtered signal to a second filter node during the first time period, wherein the second filter node is coupled to the ground supply node via a sixth capacitor;
couple the second capacitor between the second filter node and the ground supply node during the first time period;
couple the filtered signal to the second filter node via the third capacitor during the first time period; and
couple the fourth capacitor between the second filter node and the ground supply node during a fourth time period subsequent to the third time period.

19. The system of claim 14, wherein a value of the first capacitor is programmable.

20. The system of claim 14, wherein a value of the third capacitor is programmable.
